(19) United States
(12) Patent Application Publication
(10) Pub. No.: US 2015/0011026 A1
(43) Pub. Date: Jan. 8, 2015

(54) PROCESSING METHOD, PROCESSING APPARATUS, LITHOGRAPHY APPARATUS, AND METHOD OF MANUFACTURING ARTICLE

(71) Applicant: CANON KABUSHIKI KAISHA, Tokyo (JP)

(72) Inventor: Satoru Oishi, Utsunomiya-shi (JP)

(21) Appl. No.: 14/319,156

(22) Filed: Jun. 30, 2014

(30) Foreign Application Priority Data
Jul. 3, 2013 (JP) 2013-140192

(51) Int. Cl. G01B 11/14; H01L 21/66

(52) U.S. Cl. CPC G01B 11/14; H01L 22/20
USPC 438/14; 356/401

(57) ABSTRACT

The present invention provides a processing method of processing a first signal obtained by detecting an alignment mark including a plurality of mark elements to obtain a position of the alignment mark, the method including steps of performing filtering to the first signal to generate a second signal, and obtaining the position of the alignment mark based on the second signal, wherein the filtering uses a plurality of filters by which a plurality of weights are respectively given to the plurality of mark elements, all of the plurality of weights being not the same for obtaining the position.

### BACKGROUND OF THE INVENTION

1. Field of the Invention

The present invention relates to a processing method, a processing apparatus, a lithography apparatus, and a method of manufacturing an article.

2. Description of the Related Art

In a lithography apparatus such as an exposure apparatus which forms the pattern of a semiconductor device on a substrate, the pattern of the (n+1)th (n is a natural number) layer needs to be formed to overlap the pattern of the nth layer in a semiconductor wafer process. Before forming the pattern of the (n+1)th layer, the position of the pattern of the nth layer is measured (alignment measurement). The alignment measurement is performed by detecting a mark (alignment mark) formed on a substrate.

To satisfy a request for micropatterning of a semiconductor device, high alignment accuracy is necessary. The alignment accuracy needs to be, for example, about ¼ of the minimum line width of a device pattern, practically about 8 nm when the minimum line width of a device pattern is 32 nm.

In alignment measurement, for example, light traveling from an alignment mark including a plurality of mark elements is formed into an image on an image sensor. An alignment signal obtained from the image of the alignment mark is processed, obtaining the position of the alignment mark. The alignment signal generally contains various noise components which act as measurement error factors. Thus, the robustness of alignment mark measurement needs to be enhanced by applying a noise removal filter to the alignment signal.

Japanese Patent No. 4072408 has proposed a technique using a zero-phase filter as the noise removal filter so as not to generate a phase shift of a signal in noise removal. Japanese Patent No. 4072408 has disclosed that the zero-phase filter is applied to an alignment signal while changing the order, and an optimum order is determined by using the interval between the mark elements of an alignment mark as the evaluation criterion.

Recently, semiconductor device manufacturing processes have been diversified, and a CMP (Chemical Mechanical Polishing) process and the like have been introduced as planarization techniques for solving the shortage of the focal depth of an exposure apparatus. Owing to the influence of the CMP process, the mark elements of an alignment mark on a substrate tend to have asymmetrical shapes. FIGS. 20A and 20B are a schematic plan view and schematic sectional view, respectively, showing an alignment mark on a substrate having undergone the CMP process. This alignment mark includes nine mark elements arrayed in the measurement direction. As shown in FIG. 20B, the shapes of mark elements at the left and right ends of the alignment mark tend to be distorted under the influence of the CMP process. FIG. 20C is a graph showing the relationship (that is, asymmetry at each position within the alignment mark) between the position in the measurement direction and the asymmetry of the mark element. In other words, the distortion (asymmetry) of the mark element becomes larger toward the end of the alignment mark.

If the alignment mark becomes asymmetrical, a resist applied onto it also becomes asymmetrical and the alignment signal is distorted, generating an error (measurement error) in the position of the alignment mark. Such an alignment mark measurement error arising from the process is called WIS (Wafer Induced Shift). Even when the WIS changes depending on the position within the alignment mark, it is necessary to reduce the measurement error and obtain the position of the alignment mark at high accuracy.

There is a technique of applying a uniform noise removal filter to an alignment signal regardless of the position of an alignment mark, as in Japanese Patent No. 4072408. However, there is no technique considering the WIS dependent on the position within the alignment mark.

### SUMMARY OF THE INVENTION

The present invention provides, for example, a technique advantageous in terms of precision with which a position of an alignment mark is measured.

According to one aspect of the present invention, there is provided a processing method of processing a first signal obtained by detecting an alignment mark including a plurality of mark elements to obtain a position of the alignment mark, the method including steps of performing filtering to the first signal to generate a second signal, and obtaining the position of the alignment mark based on the second signal, wherein the filtering uses a plurality of filters by which a plurality of weights are respectively given to the plurality of mark elements, all of the plurality of weights being not the same for obtaining the position.

Further aspects of the present invention will become apparent from the following description of exemplary embodiments with reference to the attached drawings.

### BRIEF DESCRIPTION OF THE DRAWINGS

FIG. 1 is a schematic view showing the arrangement of an exposure apparatus as one aspect of the present invention.

FIG. 2 is a schematic view showing the arrangement of the alignment detection system of the exposure apparatus shown in FIG. 1.

FIGS. 3A and 3B are views showing an example of an alignment mark.

FIGS. 4A and 4B are views showing an example of the alignment mark.

FIG. 5 is a view showing an example of the alignment mark.

FIG. 6 is a graph schematically showing the alignment signal of the alignment mark shown in FIG. 5.

FIG. 7 is a block diagram showing the main functional modules of the signal processing unit of the exposure apparatus shown in FIG. 1.

FIG. 8 is a flowchart for explaining signal processing in the first embodiment.

FIGS. 9A and 9B are graphs for explaining a method for changing a filter shape in the first embodiment.

FIG. 10 is a view for explaining a determination method of determining a filter shape.

FIGS. 11A and 11B are graphs for explaining the determination method of determining a filter shape.

FIG. 12 is a graph for explaining the determination method of determining a filter shape.

FIG. 13 is a flowchart for explaining signal processing in the second embodiment.

FIG. 14 is a graph showing an example of the symmetry of an alignment signal.

FIG. 15 is a flowchart for explaining signal processing in the third embodiment.

FIG. 16 is a view for explaining a window function filter.

FIG. 17 is a view for explaining a window function filter.

FIG. 18 is a view for explaining a window function filter.

FIG. 19 is a flowchart for explaining signal processing in the fourth embodiment.

FIGS. 20A to 20C are views for explaining an alignment mark.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

### First Embodiment

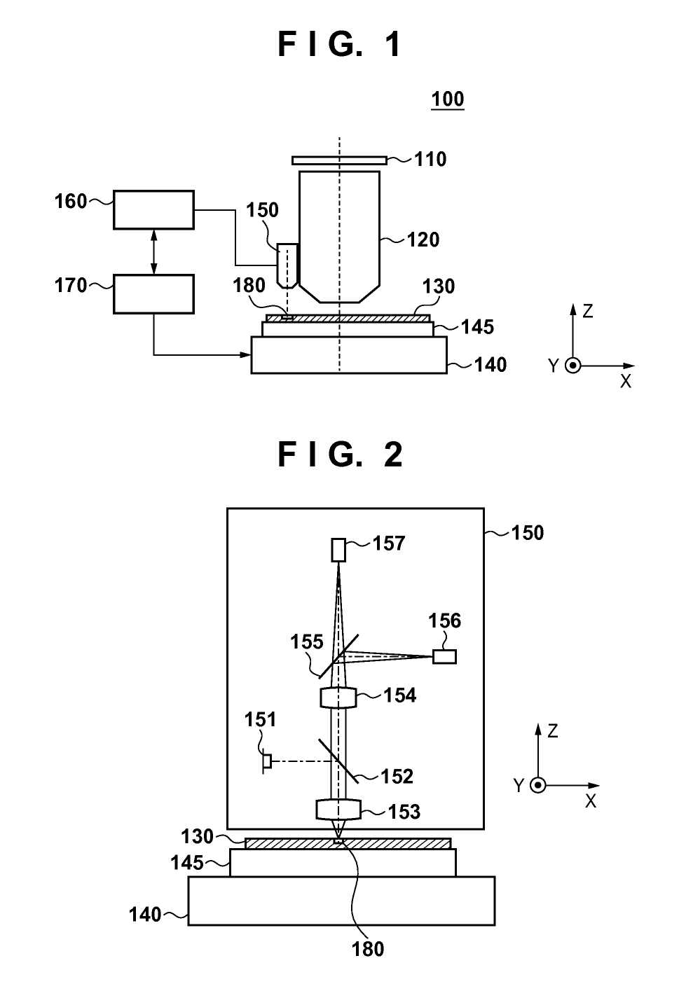

FIG. 1 is a schematic view showing the arrangement of an exposure apparatus 100 as one aspect of the present invention. The exposure apparatus 100 is, for example, a lithography apparatus which transfers (forms) a reticle pattern (circuit pattern) on a substrate by a step & scan method or a step & repeat method. The exposure apparatus 100 is suitable for a lithography process of not more than submicron order or quarter-micron order.

As shown in FIG. 1, the exposure apparatus 100 includes a projection optical system 120, chuck 145, substrate stage 140, alignment detection system 150, signal processing unit 160, and control unit 170. Although not shown in FIG. 1, the exposure apparatus 100 also includes an illumination optical system which illuminates a reticle 110 with light emitted by a light source.

The projection optical system 120 is an optical system which reduces the pattern of the reticle 110 and projects the reduced pattern to a substrate 130. The chuck 145 is placed on the substrate stage 140, and chucks the substrate 130 on which an underlying pattern and an alignment mark 180 have been formed in a preceding process. The substrate stage 140 is a stage which moves while holding the substrate 130 via the chuck 145. The substrate stage 140 positions the substrate 130 at a predetermined position. The alignment detection system 150 has a function of detecting (measuring) the alignment mark 180 formed on the substrate 130. The alignment detection system 150 forms an image of a range including the alignment mark 180 on the imaging plane. The alignment detection system 150 detects light traveling from the alignment mark 180 and acquires an alignment signal, which will be described later.

The control unit 170 includes a CPU and memory, and controls the (overall) operation of the exposure apparatus 100. The control unit 170 is electrically connected to the illumination optical system (not shown), reticle stage (not shown), substrate stage 140, and signal processing unit 160. The control unit 170 positions the substrate stage 140 (that is, the substrate 130) based on the position of the alignment mark 180 that is obtained by the alignment detection system 150 and signal processing unit 160.

A measurement principle for the alignment mark 180 will be explained with reference to FIG. 2. FIG. 2 is a schematic view showing the arrangement of the alignment detection system 150. Light emitted by an alignment light source 151 is reflected by a beam splitter 152 and illuminates, via an objective lens 153, the alignment mark 180 on the substrate 130. The light (reflected light or diffracted light) traveling from the alignment mark 180 enters a beam splitter 155 via the objective lens 153, a beam splitter 152, and a lens 154, and is split by the beam splitter 155. Sensors (light receiving elements) 156 and 157 such as CCDs detect the beams split by the beam splitter 155. The alignment detection system 150 includes the two sensors 156 and 157 in order to measure the X and Y positions of the alignment mark 180 independently. The components from the alignment light source 151 to the beam splitter 155 constitute an imaging optical system which forms the image of the alignment mark 180 on the sensors 156 and 157 arranged on imaging planes.

The alignment mark 180 is enlarged at a magnification of, for example, about ×100 via the objective lens 153 and lens 154, and forms images on the sensors 156 and 157. The sensors 156 and 157 are sensors for measuring the X and Y shifts (positions) of the alignment mark 180, and are arranged by rotating them through 90° with respect to the optical axis of the alignment detection system 150. The sensors 156 and 157 may be two-dimensional sensors, or one-dimensional sensors. In the embodiment, a cylindrical lens having power in only the measurement direction and a direction (perpendicular direction) perpendicular to the measurement direction preferably condenses light traveling from the alignment mark 180 in the measurement direction and perpendicular direction, optically integrating (averaging) the light. Since measurement principles for the X and Y positions of the alignment mark 180 are the same, measurement of the X position of the alignment mark 180 will be explained here.

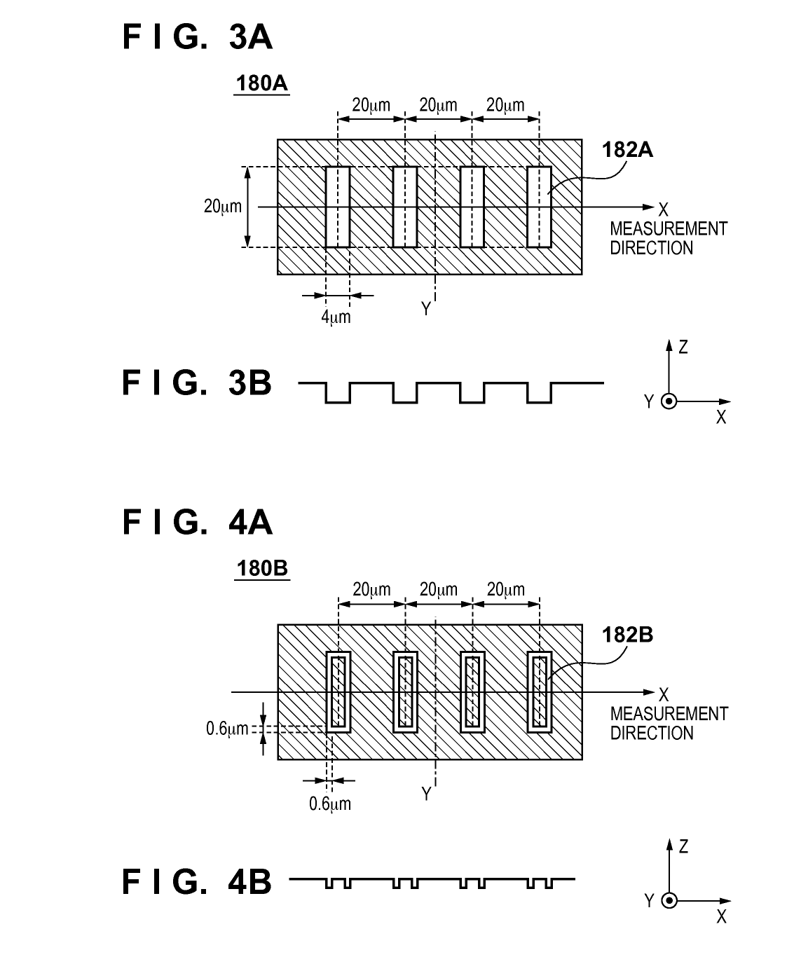

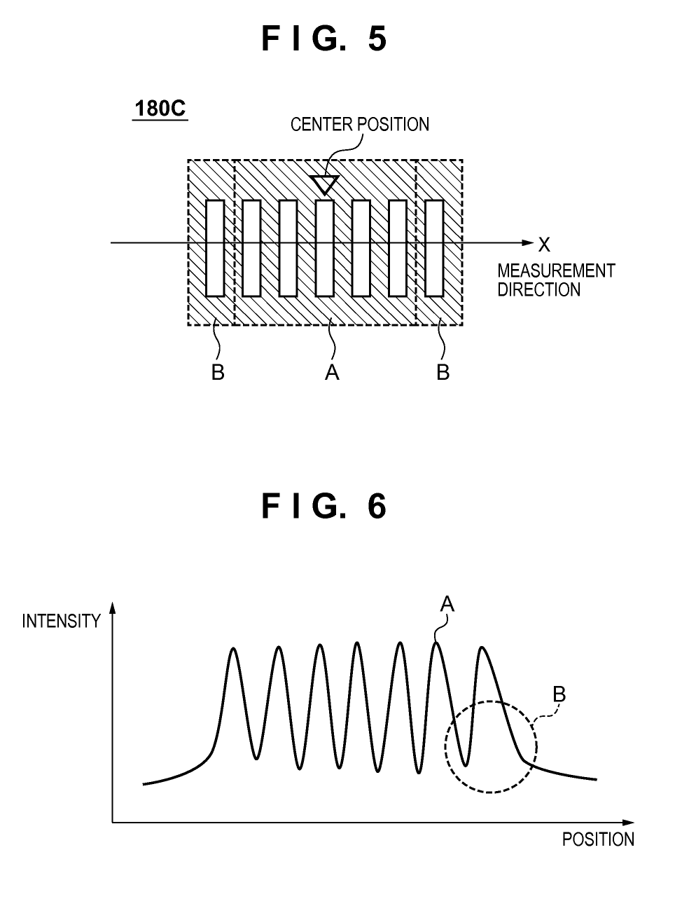

The alignment mark 180 is formed on, for example, the scribe line of each shot region of the substrate 130. As the alignment mark 180, an alignment mark 180A shown in FIGS. 3A and 3B, an alignment mark 180B shown in FIGS. 4A and 4B, and an alignment mark 180C shown in FIG. 5 are usable. FIGS. 3A and 3B are a plan view and sectional view, respectively, of the alignment mark 180A. FIGS. 4A and 4B are a plan view, respectively, and sectional view of the alignment mark 180B. FIG. 5 is a plan view of the alignment mark 180C. Note that the alignment marks 180A, 180B, and 180C will be generically called the alignment mark 180.

As shown in FIG. 3A, the alignment mark 180A includes four mark elements 182A arranged at equal intervals. As shown in FIG. 4A, the alignment mark 180B includes four mark elements 182B arranged at equal intervals. In practice, a resist is applied to the alignment marks 180A and 180B, but is not illustrated in FIGS. 3B and 4B.

As shown in FIG. 3A, the alignment mark 180A is constituted by arranging, at a 20 μm pitch in the X direction, the rectangular mark elements 182A each 4 μm wide in the X direction serving as the measurement direction and 20 μm long in the Y direction serving as the non-measurement direction. The sectional structure of the mark element 182A has a recessed shape, as shown in FIG. 3B. To the contrary, as shown in FIGS. 4A and 4B, the alignment mark 180B is constituted by the mark elements 182B each obtained by the outline of the mark element 182A with a 0.6 μm line width. Recently, the averaging effect is sometimes enhanced by increasing the number of mark elements in the measurement direction, like the alignment mark 180C shown in FIG. 5.

FIG. 6 is a graph schematically showing an alignment signal (waveform) acquired by optically detecting the alignment mark 180C shown in FIG. 5 by the sensor 156 (that is, by detecting light traveling from the alignment mark 180C). In FIG. 6, the ordinate represents the intensity of the alignment signal, and the abscissa represents the position in the measurement direction. In the alignment signal shown in FIG. 6, a portion corresponding to a region B at the end of the alignment mark 180C is distorted owing to the influence of the WIS, compared to a portion corresponding to a region A at the center of the alignment mark 180C.

The signal processing unit 160 performs alignment signal processing on such an alignment signal. As the alignment signal processing, various processes have been proposed, including a method of detecting the edge of an alignment signal to obtain the edge position, a pattern matching method using a template, and a symmetrical pattern matching method. The center position of the entire alignment mark obtained from these alignment signal processes is used as a measurement value.

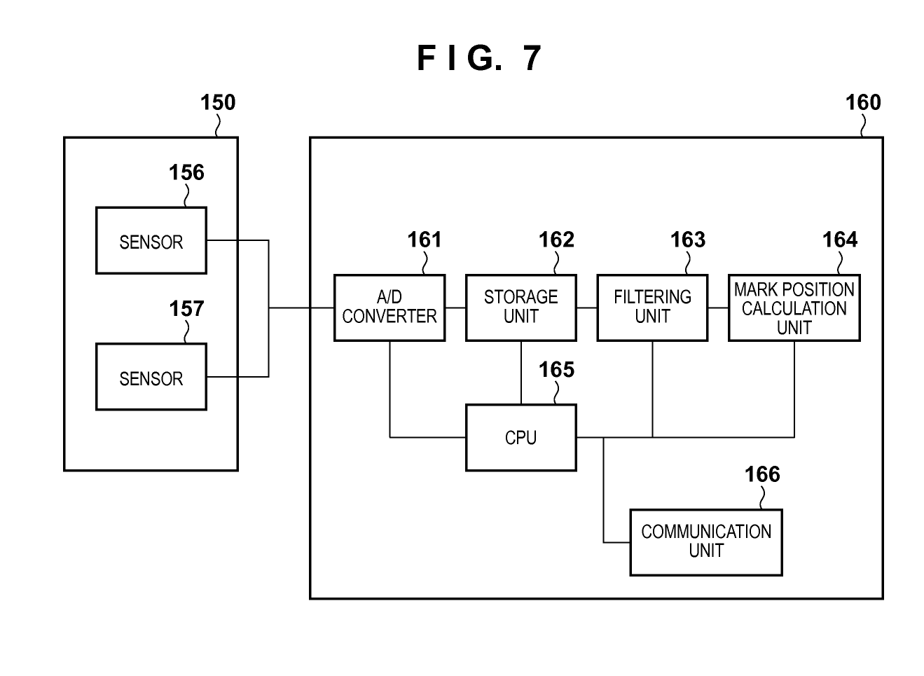

FIG. 7 is a block diagram showing the main functional modules of the signal processing unit 160. Note that the alignment detection system 150 including the sensors 156 and 157 and the imaging optical system (from the alignment light source 151 to the beam splitter 155), and the signal processing unit 160 constitute a measurement apparatus which measures the position of the alignment mark 180.

Referring to FIG. 7, alignment signals (analog signals) output from the sensors 156 and 157 are digitized via an A/D converter 161. The digital alignment signal is stored in a storage unit 162 such as a memory. A filtering unit 163 performs filtering (to be described later) on the alignment signal stored in the storage unit 162 (that is, generates an alignment signal having undergone filtering). A mark position calculation unit 164 performs the above-described alignment signal processing on the alignment signal having undergone filtering by the filtering unit 163, and obtains the position (center position) of the entire alignment mark (that is, obtains the position of the alignment mark). A CPU 165 is connected to the A/D converter 161, storage unit 162, filtering unit 163, and mark position calculation unit 164, and outputs a control signal to control the operation. A communication unit 166 transmits/receives necessary data, control instructions, and the like to/from the control unit 170.

In filtering (digital signal processing) in the embodiment, measurement operations in the X and Y directions are independent. Hence, signal processing for obtaining the position of an alignment mark is one-dimensional signal processing. When the sensors 156 and 157 are two-dimensional sensors, two-dimensional digital signals acquired by the alignment detection system 150 are accumulated and averaged in a direction perpendicular to the measurement direction, and are converted into one-dimensional line signals. Then, the one-dimensional line signals undergo filtering in the embodiment.

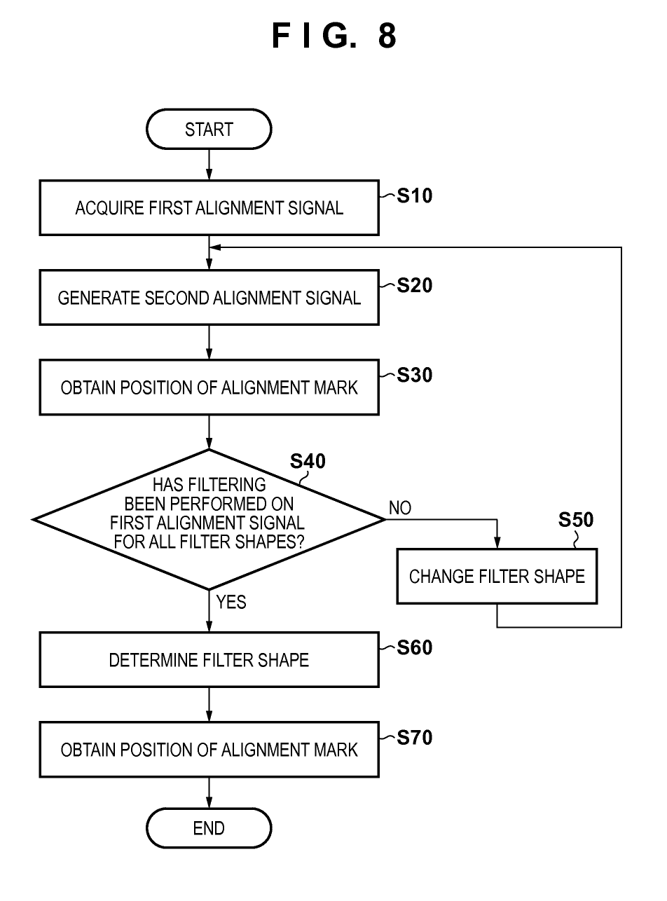

FIG. 8 is a flowchart for explaining signal processing in the first embodiment. In step S10, the alignment detection system 150 detects light traveling from the alignment mark 180 formed on the substrate 130, and acquires the first alignment signal.

In step S20, filtering using a zero-phase filter is performed on the first alignment signal acquired in step S10, thereby generating the second alignment signal. In step S30, the position of the alignment mark 180 is obtained based on the second alignment signal generated in step S20.

Here, the zero-phase filter will be explained. The filter used in step S20 is used to calculate a weighted moving average for noise removal. For example, the weighted moving average is given by:

$$\begin{matrix}y ( n ) = \frac{1}{L} {\sum }_{j = - m}^{m} w ( j ) x ( n + j ) & ( 1 ) \\ L = {\sum }_{j = - m}^{m} w ( j ) & ( 2 )\end{matrix}$$

where x(n+j) is the data string before performing filtering, w(j) is the weight (filter coefficient) on x(n+j), y(n) is the data string after performing filtering, and L is the sum of the weights w(j). The weighted moving average filter w(j) is calibrated as a zero-phase filter in which the phase characteristic (phase shift) is 0 or equal to or smaller than an allowance in the entire frequency band.

The alignment signal of the alignment mark 180 output from the alignment detection system 150 contains a WIS at the end of the alignment mark 180, a noise component of a relatively high frequency, and the like. The filter shape of the zero-phase filter in the embodiment differs between the region A at the center of the alignment mark 180 and the region B at the end of the alignment mark 180. In other words, filtering in the embodiment uses a plurality of filters configured to give, to respective mark elements constituting the alignment mark 180, different weights used to obtain the position of the alignment mark 180. More specifically, filtering uses a plurality of filters configured to decrease, from the center to end of the alignment mark 180, weights given to respective mark elements constituting the alignment mark 180.

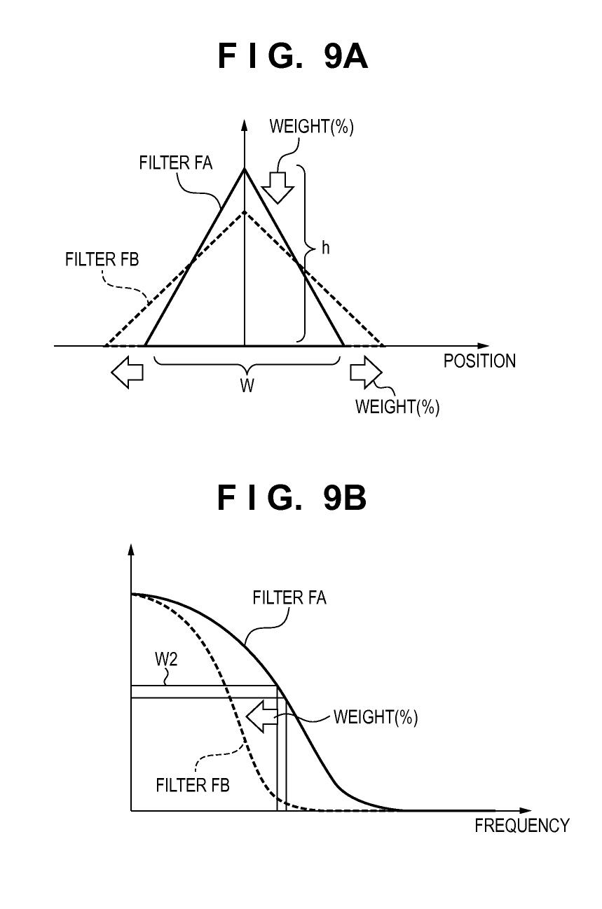

A method for changing a filter shape in the embodiment will be explained with reference to FIGS. 9A and 9B. FIG. 9A is a graph for explaining a method for changing a filter shape in the spatial region. FIG. 9B is a graph for explaining a method for changing a filter shape in the spatial frequency region.

FIG. 9A shows an example of the shape of a filter FA in the region A at the center of the alignment mark 180, and an example of the shape of a filter FB in the region B at the end of the alignment mark 180. Noise to be considered in the embodiment includes a noise component (for example, electrical noise) of a relatively high frequency added to the alignment signal, and a noise component (for example, WIS) of a lower frequency. The filter FA is a filter which removes a high-frequency noise component. The filter shape is changed by using the filter FA as a reference (template) and changing its height h and width W at the same ratio Weight. For example, a filter obtained by decreasing the height h by 10% and increasing the width W by 5% on each of the left and right sides, that is, by a total of 10% is defined as the filter FB. In this manner, the shape of the filter FB is changed while changing the ratio Weight by every 10%. The embodiment has a feature of changing the height h and width W so that the sums of coefficients coincide with each other between the filters FA and FB in the spatial region. This is because the DC components of the intensities of alignment signals after filtering need to coincide with each other.

FIG. 9B shows an example of the filters FA and FB in the spatial frequency region. In FIG. 9B, the ordinate represents the amplitude, and the abscissa represents the frequency. The filter shape may be changed by using, as a reference, the filter FA which removes a high-frequency noise component (for example, electrical noise), and decreasing, at a given ratio Weight, a width or band W2 of the frequency until the amplitude of the filter FA changes from the peak to half of that. For example, a filter obtained by decreasing the width W2 at a ratio of 10% is defined as the filter FB. In this fashion, the shape of the filter FB may be changed while increasing the ratio Weight by every 10%. Note that amplitudes at a zero frequency coincide with each other between the filters FA and FB in the spatial frequency region. This is because the DC components of alignment signals after filtering need to coincide with each other, as in the above description regarding FIG. 9A.

Referring back to FIG. 8, in step S40, it is determined whether filtering has been performed on the first alignment signal for all filter shapes. If filtering has not been performed on the first alignment signal for all filter shapes, the process shifts to step S50. If filtering has been performed on the first alignment signal for all filter shapes, the process shifts to step S60.

In step S50, the filter shape is changed by using the above-described method for changing a filter shape. After the filter shape is changed, the process returns to step S20 in order to perform filtering on the first alignment signal with this filter shape. Steps S20 to S50 are repeated until filtering is performed on the first alignment signal for all filter shapes.

In step S60, an optimum filter shape is determined from all filter shapes changed in step S50. A determination method of determining a filter shape will be described in detail later.

In step S70, the position of the alignment mark 180 is obtained based on the filter shape determined in step S60. More specifically, filtering is performed on the first alignment signal with the filter shape determined in step S60, thereby generating the second alignment signal. Based on the second alignment signal, the position of the alignment mark 180 is calculated. In FIG. 8, the second alignment signal corresponding to the filter shape determined in step S60, and the position of the alignment mark 180 have been obtained in steps S20 and S30. In step S70, a position of the alignment mark 180 that corresponds to the filter shape determined in step S60 may be selected (extracted) from positions of the alignment mark 180 that correspond to all filter shapes, respectively.

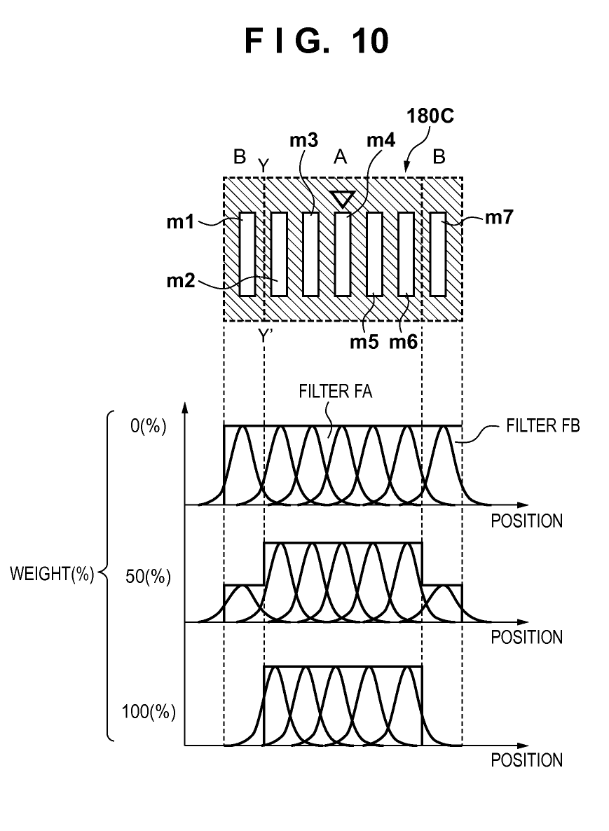

The determination method of determining a filter shape will be explained with reference to FIGS. 10, 11A, 11B, and 12. FIG. 10 is a view showing an example of the shape of a filter (zero-phase filter) for filtering performed on the alignment mark 180C. FIG. 10 shows a shape defined by a Gaussian function as the filter shape. However, any shape is applicable as long as it is defined by a function symmetrical about the center axis of the alignment mark 180C. In FIG. 10, the shape of the filter FA in the region A at the center of the alignment mark 180C is constant. However, the shape of the filter FB in the region B at the end of the alignment mark 180C changes in accordance with a change of Weight. This represents that the filter shape (weighting) is changeable in accordance with the position of a mark element constituting the alignment mark 180C. FIG. 10 shows an example in which the alignment mark 180C includes seven mark elements m1 to m7, and the mark elements m1 and m7 out of the mark elements m1 to m7 fall within the regions B at the ends of the alignment mark 180C. A border Y-Y′ between the regions A and B bisects the distance between the centers of the mark elements m1 and m2.

Next, a method of obtaining the center position of the alignment mark 180C for each Weight will be explained. More specifically, the above-described alignment signal processing is applied to the alignment signal (second alignment signal) y(n) having undergone filtering according to equation (1). Here, a case in which a symmetrical pattern matching method is applied will be explained.

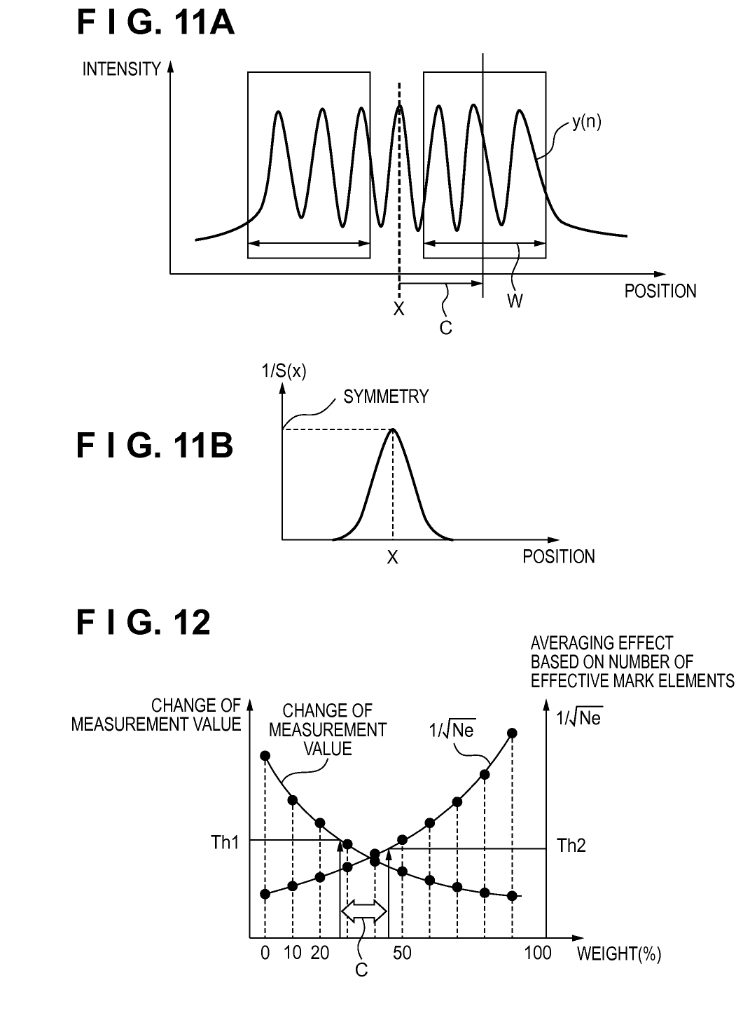

First, a folding evaluation value S(x) of the alignment signal is defined for the alignment signal y(n) having undergone filtering:

$$S ( x ) = {\sum }_{j = c - w / 2}^{c + w / 2} \vert y ( x + j ) - y ( x - j ) \vert \qquad ( 3 )$$

where C and W are the processing windows, in which C is the distance from a point x of interest and W is the processing range, respectively. FIG. 11A is a graph showing the relationship between the alignment signal y(n), and a processing window for calculating the folding evaluation value S(x). FIG. 11B shows the result of obtaining, in the measurement direction, the reciprocal 1/S(x) of the folding evaluation value S(x) represented by equation (3) while changing the point x of interest.

As the center position of the alignment mark 180C, the peak (maximum value) shown in FIG. 11B is calculated at a resolution equal to or lower than the pixel. For example, several points near the peak may be approximated by a quadratic function to define the peak as the center position of the alignment mark 180C. Alternatively, a barycentric value obtained from several points near the peak may be defined as the center position of the alignment mark 180C.

FIG. 12 shows a change of the center position (measurement value) of the alignment mark 180C with respect to the ratio Weight shown in FIGS. 9A and 9B. FIG. 12 shows a change of the measurement value of the alignment mark 180C when the ratio Weight is changed by every 10%. As the ratio Weight comes close to 100%, the influence of the WIS on the alignment signal decreases, and the change of the measurement value also decreases.

The number Ne of effective mark elements is defined by the following equation (4). The number Ne of effective mark elements is the number of mark elements used when obtaining the position of an alignment mark (number of mark elements obtained from a plurality of weights, out of a plurality of mark elements):

$$Ne = {\sum }_{k = 1}^{M} α ( k ) \qquad ( 4 )$$

where k is the number of the mark element of the alignment mark, M is the total number of mark elements of the alignment mark, and α(k) is a numerical value representing the weight of the mark element k that takes a range of 0 to 1. α(k)=1 by using, as a reference, a mark element in the region A at the center of the alignment mark. In contrast, α(k)=1−Weight for a mark element to which the ratio Weight in the region B at the end of the alignment mark is applied. As the ratio Weight in the region B at the end of the alignment mark comes close to 100% (=1), α(k) becomes equal to 0, and thus the number Ne of effective mark elements obtained from equation (4) decreases. In FIG. 12, 1/√Ne is the averaging effect based on the number of effective mark elements. FIG. 12 shows even the averaging effect 1/√Ne with respect to the ratio Weight in the region B at the end of the alignment mark.

In the embodiment, in terms of the averaging effect, the number Ne of effective mark elements represented by equation (4) is preferably large, that is, the averaging effect 1/√Ne based on the number Ne of effective mark elements is preferably small. In terms of reduction of the influence of the WIS, a change of the measurement value of the alignment mark with respect to the ratio Weight or weight α(k) is preferably small. In FIG. 12, therefore, a filter shape corresponding to a range C of the ratio Weight in which a change of the measurement value of the alignment mark is equal to or smaller than a predetermined threshold Th1 and the averaging effect 1/√Ne is equal to or smaller than a threshold Th2 is determined as the filter shape of the filter FB. In this fashion, according to the embodiment, the shape of each filter is determined based on a change of the position of the alignment mark obtained from the second alignment signal upon changing the weight (weighting), and the number of mark elements obtained from a plurality of weights, out of a plurality of mark elements.

### Second Embodiment

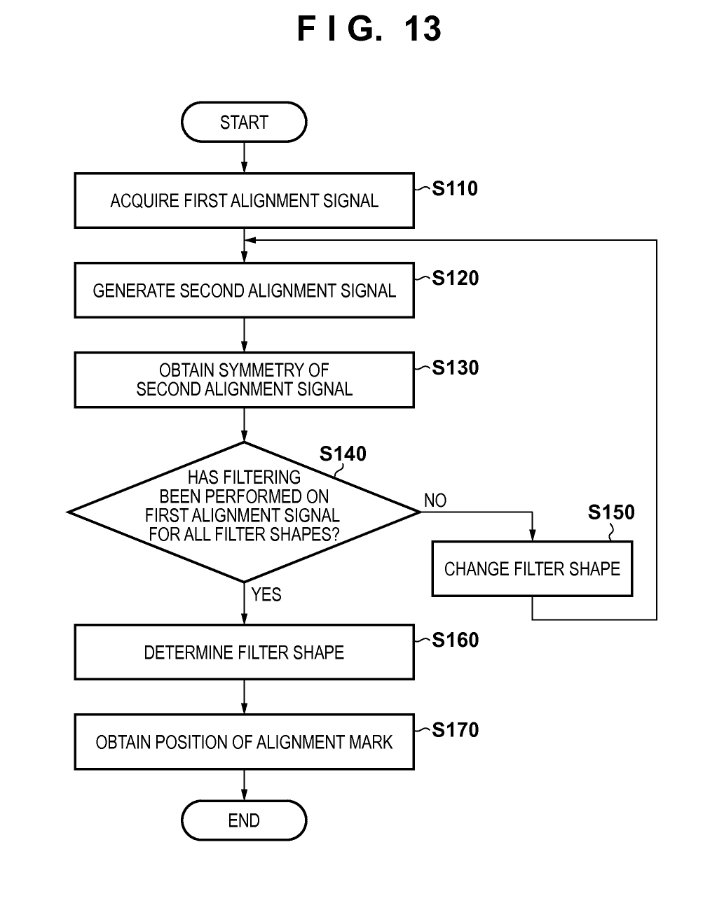

In the second embodiment, the filter shape is determined based on the symmetry of an alignment signal. FIG. 13 is a flowchart for explaining signal processing in the second embodiment. In step S110, an alignment detection system 150 detects light traveling from an alignment mark 180 formed on a substrate 130, and acquires the first alignment signal.

In step S120, filtering using a zero-phase filter is performed on the first alignment signal acquired in step S110, thereby generating the second alignment signal. In step S130, the symmetry of the second alignment signal generated in step S120 is obtained.

Here, the symmetry of the alignment signal in the embodiment will be explained. In the embodiment, the symmetry of the alignment mark uses the folding evaluation value S(x) represented by equation (3). FIG. 11B shows the result of obtaining, in the measurement direction, the reciprocal 1/S(x) of the folding evaluation value S(x) represented by equation (3). The peak (maximum value) is defined as the symmetry DS (Degree of Symmetry) of the alignment signal:

DS=max[1/S(x)] (5)

In step S140, it is determined whether filtering has been performed on the first alignment signal for all filter shapes. If filtering has not been performed on the first alignment signal for all filter shapes, the process shifts to step S150. If filtering has been performed on the first alignment signal for all filter shapes, the process shifts to step S160.

In step S150, the filter shape is changed by using the above-described method for changing a filter shape. After the filter shape is changed, the process returns to step S120 in order to perform filtering on the first alignment signal with this filter shape. Steps S120 to S150 are repeated until filtering is performed on the first alignment signal for all filter shapes.

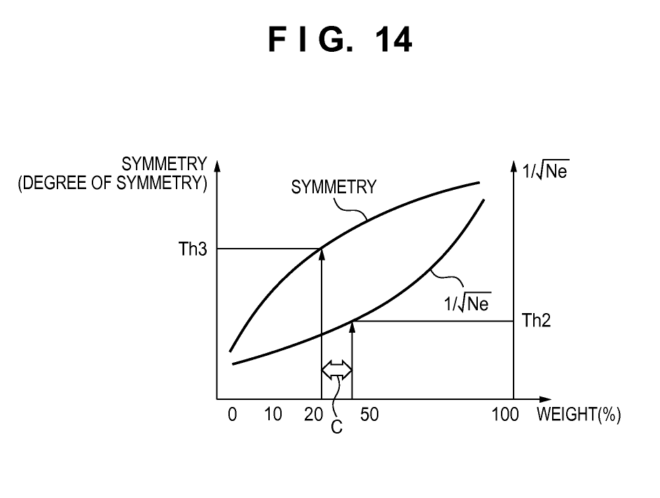

In step S160, an optimum filter shape is determined from all filter shapes changed in step S150. A determination method of determining a filter shape in the embodiment will be described. FIG. 14 shows the result of obtaining the symmetry of the alignment signal while the ratio Weight of the filter shape applied to the region B at the end of the alignment mark is changed by, for example, every 10%. FIG. 14 shows even the averaging effect 1/√Ne based on the number of effective mark elements with respect to the ratio Weight, as in the first embodiment (FIG. 12). In step S160, a filter shape corresponding to a range C′ of the ratio Weight in which the symmetry of the alignment signal is equal to or larger than a threshold Th3 and the averaging effect 1/√Ne is equal to or smaller than a threshold Th2 in FIG. 14 is determined as an optimum filter shape. In this way, the filter shape is determined based on the symmetry of the waveform of the second alignment signal, and the number of mark elements obtained from a plurality of weights, out of a plurality of mark elements.

Referring back to FIG. 13, in step S170, the position of the alignment mark 180 is obtained based on the filter shape determined in step S160.

### Third Embodiment

The first and second embodiments have described a case in which (the shape of) the filter w(j) is convoluted for the data string x(n), as represented by equation (1). This is effective particularly when the data string x(n) contains a high-frequency noise component. The third embodiment will explain a case in which a high-frequency noise component contained in the data string x(n) is small, that is, high-frequency noise need not be reduced by a filter (zero-phase filter). In the embodiment, a filter applied to the data string x(n) includes a plurality of filters having a plurality of values of a window function in which not the convolution but the weight becomes 0 at the end of an alignment mark.

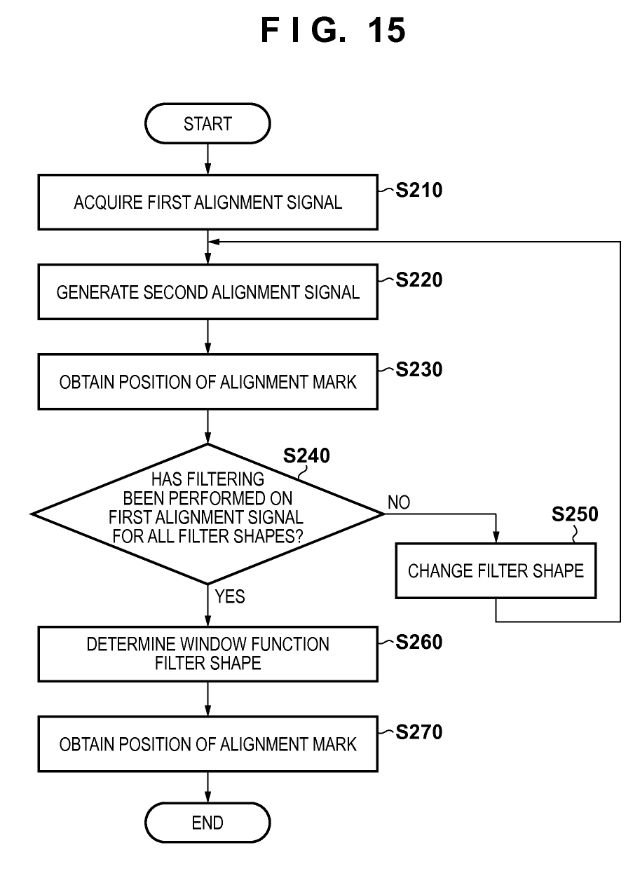

FIG. 15 is a flowchart for explaining signal processing in the third embodiment. In step S210, an alignment detection system 150 detects light traveling from an alignment mark 180 formed on a substrate 130, and acquires the first alignment signal.

In step S220, filtering using a window function filter is performed on the first alignment signal acquired in step S210, thereby generating the second alignment signal:

y(n)=K(n)×x(n) (6)

where x is the data string before performing filtering, K is the window function filter, y is the data string after performing filtering, and n is the sample number of measurement data.

In step S230, the position of the alignment mark 180 is obtained based on the second alignment signal generated in step S220.

In step S240, it is determined whether filtering has been performed on the first alignment signal for all filter shapes. If filtering has not been performed on the first alignment signal for all filter shapes, the process shifts to step S250. If filtering has been performed on the first alignment signal for all filter shapes, the process shifts to step S260.

In step S250, the filter shape is changed. After the filter shape is changed, the process returns to step S220 in order to perform filtering on the first alignment signal with this filter shape. Steps S220 to S250 are repeated until filtering is performed on the first alignment signal for all filter shapes.

In step S260, an optimum window function filter shape is determined from all filter shapes changed in step S250.

In step S270, the position of the alignment mark 180 is obtained based on the window function filter shape determined in step S260.

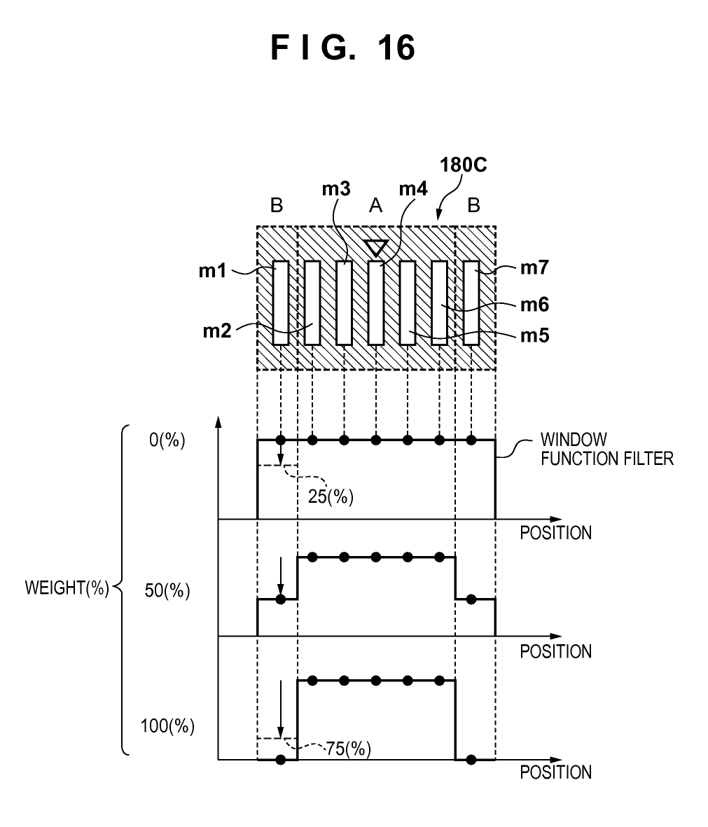

FIG. 16 is a view for explaining (the shape of) the window function filter in the third embodiment. In the window function filter shown in FIG. 16, a filter shape corresponding to one mark element of an alignment mark 180C is uniform. Hence, a filter shape corresponding to a mark element m1 is defined by a size obtained by subtracting a uniform ratio Weight (%) from a window function filter, serving as the reference (K(n)=1), in the region A at the center of the alignment mark 180C. For example, when the ratio Weight in the region B at the end of the alignment mark 180C is 50%, a filter shape corresponding to the mark element m1 is obtained as K(n)=0.5.

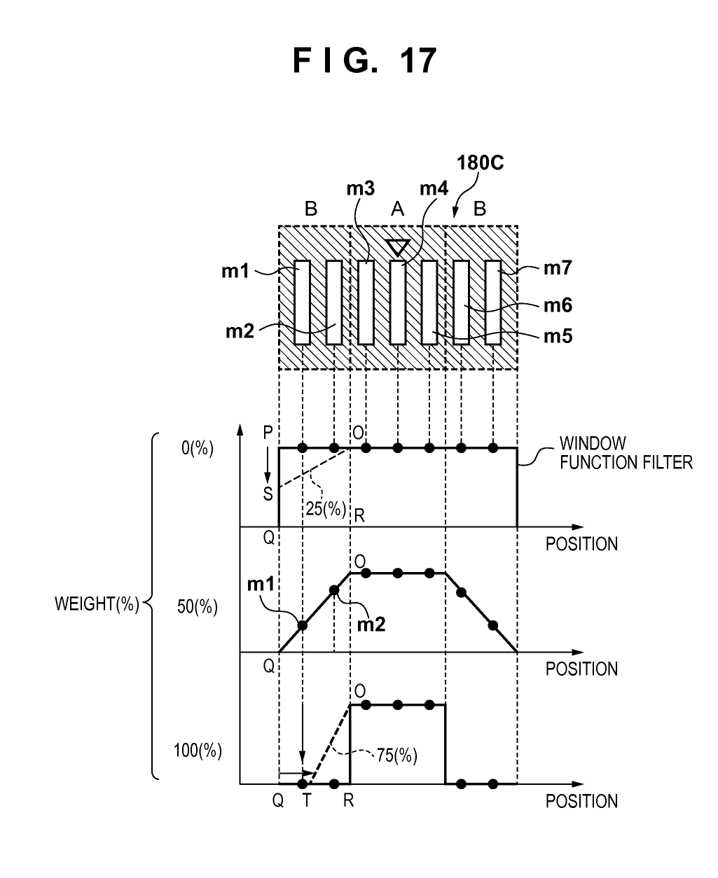

FIG. 17 shows a case in which two mark elements (that is, mark elements m1 and m2, or mark elements m6 and m7) fall within each of the regions B at the ends of the alignment mark 180C, and the window function filter shape is not uniform. In FIG. 17, when the ratio Weight is 50%, window function filter shapes corresponding to the mark elements m1 and m2 are defined by lines connecting a line segment OQ. When the ratio Weight is 25%, window function filter shapes corresponding to the mark elements m1 and m2 are defined by a line segment OS in which S is the middle point of a line segment PQ. Similarly, when the ratio Weight is 75%, window function filter shapes corresponding to the mark elements m1 and m2 are defined by a line segment OT in which T is the middle point of a line segment OR.

In this manner, a window function filter whose shape is defined in accordance with the position of a mark element of the alignment mark is applied to the alignment signal, and an optimum window function filter shape is determined, as in the first embodiment. The number Ne of effective mark elements necessary for determination (optimization) of a window function filter shape will be explained. In FIG. 16, when the ratio Weight is 50%, it suffices to set α(k)=0.5 for the region B at the end of the alignment mark 180C in equation (4), set α(k)=1 for the region A at the center of the alignment mark 180C, and determine a window function filter shape. To the contrary, in FIG. 17, when the ratio Weight is 50%, two mark elements fall within the region B at the end of the alignment mark 180C. Thus, as for the line segment OQ, the window function filter shape is determined based on the sizes of filters corresponding to the positions of the two mark elements. More specifically, α(1)=0.25 for the mark element m1, α(2)=0.75 for the mark element m2, and equation (4) is solved.

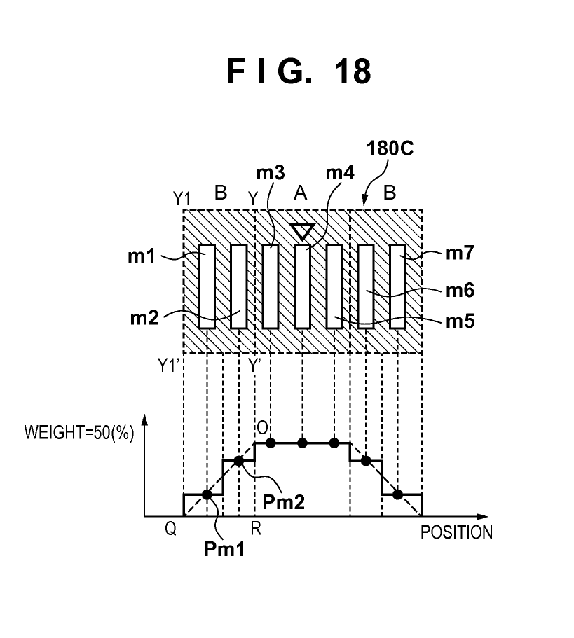

In FIG. 17, when the ratio Weight in the region B at the end of the alignment mark 180C is 50%, window function filter shapes corresponding to the mark elements m1 and m2 are defined by lines connecting the line segment OQ. However, the window function filter shape may be defined uniformly for each mark element of the alignment mark 180C, as shown in FIG. 18. Referring to FIG. 18, the window function filter shape is defined stepwise in accordance with the mark element. A border Y-Y′ between the region A at the center of the alignment mark 180C and the region B at the end of the alignment mark 180C bisects the distance between the centers of the mark elements m1 and m2. Also, a border Y1-Y1′ at the left end of the region B is spaced apart from the mark element m1 by half the distance between mark elements. A point Pm1 corresponding to the center position of the mark element m1 is a point which internally divides the line segment OQ at 3:1. A point Pm2 corresponding to the center position of the mark element m2 is a point which internally divides the line segment OQ at 1:3. From this, window function filter shapes corresponding to the respective mark elements m1 and m2 suffice to be set To heights corresponding to ¼ and ¾ of the height (line segment OR) of the region A.

### Fourth Embodiment

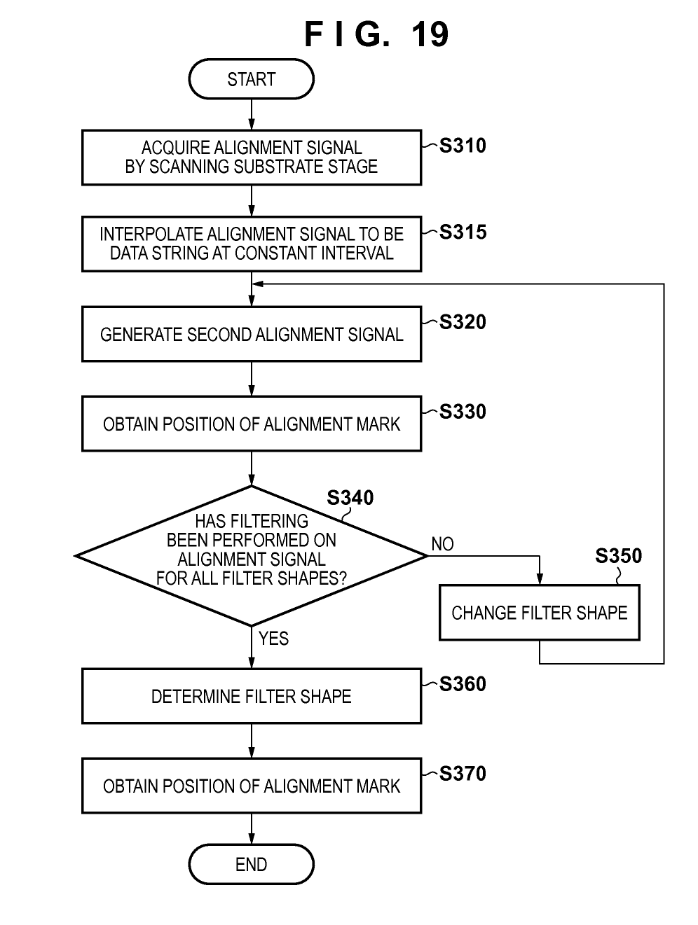

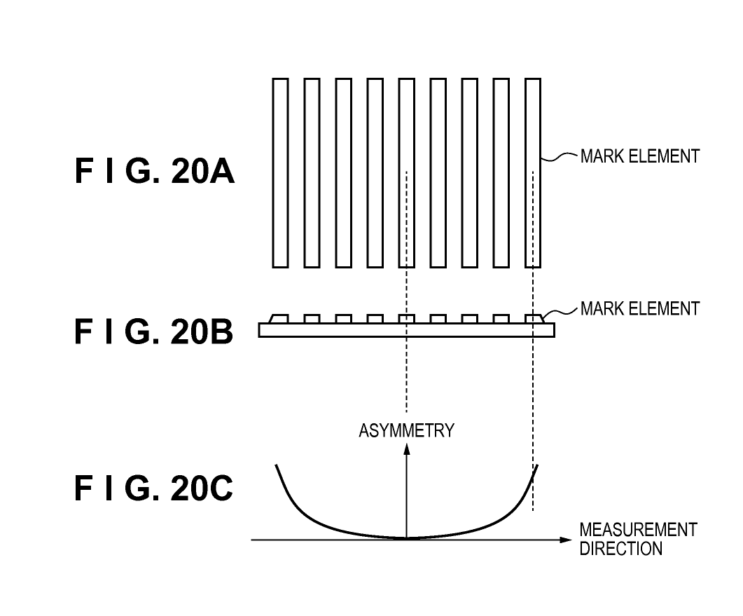

The fourth embodiment will describe a case in which the alignment signal of an alignment mark is acquired by scanning a substrate stage. First, acquisition of an alignment signal by scanning the substrate stage will be exemplified. For example, a plurality of mark elements of the alignment mark are irradiated with light while scanning the substrate stage. A sensor (photoelectric conversion element) detects the intensity of light (reflected light) traveling from the mark elements sampled at a constant interval in time series. At this time, owing to the scanning accuracy of the substrate stage, the interval in the measurement direction becomes inconstant, unlike constant-interval sampling. The interval in the measurement direction needs to be interpolated to be constant. However, linear interpolation or the like generates a measurement error owing to the influence of an error of each data of inconstant-interval sampling. In the embodiment, the interval in the measurement direction is interpolated to be constant, as shown in FIG. 19.

FIG. 19 is a flowchart for explaining signal processing in the fourth embodiment. In step S310, an alignment mark signal is acquired by scanning a substrate stage 140, as described above. The alignment signal acquired in step S310 is a data string at an inconstant interval with respect to the position of the substrate stage 140 that is measured by an interferometer or the like.

In step S315, the alignment mark signal acquired in step S310 is interpolated to be a data string at a constant interval (equal intervals) by spline interpolation or the like. As a result, even if the alignment signal acquired in step S310 is an inconstant-interval data string, the influence of the WIS at the two ends of the alignment mark can be reduced, and the position of the alignment mark can be measured at high accuracy.

In step S320, filtering using a zero-phase filter is performed on the alignment signal interpolated to be a constant-interval data string in step S315, thereby generating the second alignment signal. In step S330, the position of an alignment mark 180 is obtained based on the second alignment signal generated in step S320.

In step S340, it is determined whether filtering has been performed for all filter shapes on the alignment signal interpolated to be a constant-interval data string. If filtering has not been performed for all filter shapes on the alignment signal interpolated to be a constant-interval data string, the process shifts to step S350. If filtering has been performed for all filter shapes on the alignment signal interpolated to be a constant-interval data string, the process shifts to step S360.

In step S350, the filter shape is changed by using the above-described method for changing a filter shape. After the filter shape is changed, the process returns to step S320 in order to perform, with this filter shape, filtering on the alignment signal interpolated to be a constant-interval data string. Steps S320 to S350 are repeated until filtering is performed on the alignment signal interpolated to be a constant-interval data string.

In step S360, an optimum filter shape is determined from all filter shapes changed in step S350.

In step S370, the position of the alignment mark 180 is obtained based on the filter shape determined in step S360.

### Fifth Embodiment

In the fifth embodiment, inconstant-interval sampling is performed actively when acquiring the alignment signal of an alignment mark by scanning a substrate stage. As described above, the influence of the WIS is great at the end of an alignment mark, so measurement data are acquired intensively in such a region where the WIS occurs. More specifically, the time-series sampling time is shortened, or for equal-time sampling, the scanning speed of the substrate stage is decreased. Since measurement data in the region where the WIS occurs can be acquired intensively, the filter shape can be determined based on detailed WIS information, and the measurement error of the position of the alignment mark can be reduced.

The fourth and fifth embodiments have described a case in which the substrate stage is scanned. However, the same effects as those described above can be obtained even when light irradiating an alignment mark (mark element) is scanned (that is, beam scanning method).

As described in each embodiment, the exposure apparatus 100 can measure, at high accuracy, the alignment mark 180 formed on the substrate 130 regardless of generation of the WIS. The exposure apparatus 100 can therefore maintain high alignment accuracy, form (transfer) a micropattern to the substrate 130, and thus is suitable for manufacturing an article such as a microdevice (for example, a semiconductor device) or an element having a microstructure. The method of manufacturing an article includes a step of forming a pattern on a substrate using the exposure apparatus 100, and a step of processing the substrate on which the pattern has been formed by the preceding step (for example, a step of performing development or etching). Further, the method of manufacturing the article can include other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-140192 filed on Jul. 3, 2013, which is hereby incorporated by reference herein in its entirety.

1. A processing method of processing a first signal obtained by detecting an alignment mark including a plurality of mark elements to obtain a position of the alignment mark, the method comprising steps of:
performing filtering to the first signal to generate a second signal; and
obtaining the position of the alignment mark based on the second signal,
wherein the filtering uses a plurality of filters by which a plurality of weights are respectively given to the plurality of mark elements, all of the plurality of weights being not the same for obtaining the position.

2. The method according to claim 1, wherein the plurality of weights of the plurality of filters are symmetrical with respect to a center of the first signal.

3. The method according to claim 1, wherein the plurality of weights of the plurality of filters are decreased from a center of the first signal toward an end of the first signal.

4. The method according to claim 1, wherein the plurality of weights of the plurality of filters respective have a plurality of values of a window function which has 0 as a value thereof at an end of the first signal.

5. The method according to claim 1, wherein the plurality of weights are determined based on a change in the position of the alignment mark obtained based on the second signal in case where the plurality of weights are changed, and number of mark elements, of the plurality of mark elements, obtained based on the plurality of weights.

6. The method according to claim 1, wherein the plurality of weights are determined based on symmetry of a waveform of the second signal obtained based on the plurality of weights, and number of mark elements, of the plurality of mark elements, obtained based on the plurality of weights.

7. The method according to claim 1, wherein the first signal is obtained by scanning light across the plurality of mark elements.

8. The method according to claim 1, wherein the first signal is obtained by performing spline interpolation to a signal obtained by scanning light across the plurality of mark elements.

9. The method according to claim 1, wherein one of the plurality of weights corresponding to an end one of the plurality of mark elements is between zero and one.

10. A processing apparatus for processing a first signal obtained by detecting an alignment mark including a plurality of mark elements, to obtain a position of the alignment mark, the apparatus comprising:
a processor configured to perform filtering to the first signal to generate a second signal, and obtain the position of the alignment mark based on the second signal,
wherein the filtering uses a plurality of filters by which a plurality of weights are respectively given to the plurality of mark elements, all of the plurality of weights being not the same for obtaining the position.

11. The apparatus according to claim 10, wherein one of the plurality of weights corresponding to an end one of the plurality of mark elements is between zero and one.

12. A lithography apparatus for forming a pattern on a substrate, the apparatus comprising a processing apparatus for processing a first signal obtained by detecting an alignment mark including a plurality of mark elements, to obtain a position of the alignment mark, the processing apparatus comprising a processor configured to perform filtering to the first signal to generate a second signal, and obtain the position of the alignment mark based on the second signal,
wherein the filtering uses a plurality of filters by which a plurality of weights are respectively given to the plurality of mark elements, all of the plurality of weights being not the same for obtaining the position, and wherein the processing apparatus is configured to obtain a position of an alignment mark formed on the substrate.

13. A method of manufacturing an article, the method comprising steps of:
forming a pattern on a substrate using a lithograph apparatus; and
processing the substrate, on which the pattern has been formed, to manufacture the article,
wherein the lithograph apparatus includes a processing apparatus configured to obtain a position of an alignment mark formed on the substrate,
wherein the processing apparatus processes a first signal obtained by detecting the alignment mark including a plurality of mark elements, to obtain the position of the alignment mark, and includes:
a processor configured to perform filtering to the first signal to generate a second signal, and obtain the position of the alignment mark based on the second signal,
wherein the filtering uses a plurality of filters by which a plurality of weights are respectively given to the plurality of mark elements, all of the plurality of weights being not the same for obtaining the position.
